(19) United States
(12) Patent Application Publication
(10) Pub. No.: US 2008/0237811 A1
(43) Pub. Date: Oct. 2, 2008

(54) METHOD FOR PRESERVING PROCESSING HISTORY ON A WAFER

(76) Inventors: Rohit Pal, Fishkill, NY (US); David F. Brown, Pleasant Valley, NY (US)

Correspondence Address: WILLIAMS, MORGAN & AMERSON, 10333 RICHMOND, SUITE 1100, HOUSTON, TX, 77042, US

(21) Appl. No.: 11/694,057

(22) Filed: Mar. 30, 2007

(51) Int. Cl. H01L 23/544

(52) U.S. Cl. 257/632

(57) ABSTRACT

A method for capturing process history includes performing at least a first process for forming features on a semiconducting substrate. A first cap is formed over a first region of the semiconducting substrate after performing the first process. At least a second process is performed for forming the features in a second region other than the first region while leaving the first cap in place to thereby prevent the features in the first region covered by the first cap from being exposed to the second process. A first characteristic of a first feature is measured in the first region, and a second characteristic of a second feature in the second region is measured. A wafer includes a first partially completed feature disposed in a first region. A first cap is formed above the first partially completed feature. A second partially completed feature is disposed in a second region of the wafer different than the first region. The second partially completed feature is at a later stage of completion than the first partially completed feature.

### CROSS-REFERENCE TO RELATED APPLICATIONS

Not applicable.

### BACKGROUND OF THE INVENTION

The present invention relates generally to manufacturing and, more particularly, to a method for preserving processing history on a wafer.

The technology explosion in the manufacturing industry has resulted in many new and innovative manufacturing processes. Today's manufacturing processes, particularly semiconductor manufacturing processes, call for a large number of important steps. These process steps are usually vital, and therefore, require a number of inputs that are generally fine-tuned to maintain proper manufacturing control.

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (e.g., etching, doping, ion implanting, or the like), to the packaging and final testing of the completed device, are so different from one another and specialized that the processes may be performed in different manufacturing locations that contain different control schemes.

Generally, a set of processing steps is performed across a group of semiconductor wafers, sometimes referred to as a lot. For example, a process layer that may be composed of a variety of different materials may be formed across a semiconductor wafer. Thereafter, a patterned layer of photoresist may be formed across the process layer using known photolithography techniques. Typically, an etch process is then performed across the process layer using a patterned layer of photoresist as a mask. This etching process results in the formation of various features or objects in the process layer. Such features may be used as, for example, a gate electrode structure for transistors. Many times, trench isolation structures are also formed across the substrate of the semiconductor wafer to isolate electrical areas across a semiconductor wafer.

The manufacturing tools within a semiconductor manufacturing facility typically communicate with a manufacturing framework or a network of processing modules. Each manufacturing tool is generally connected to an equipment interface. The equipment interface is connected to a machine interface to which a manufacturing network is connected, thereby facilitating communications between the manufacturing tool and the manufacturing framework. In some cases, the machine interface can generally be part of an advanced process control (APC) system. The APC system initiates a control script, which can be a software program that automatically retrieves the data needed to execute a manufacturing process.

During the integration of a new technology element (e.g., stressed layers, high-K metal gates, etc.) into a design, multiple wafer in process (WIP) turns are implemented in a serial fashion. Each WIP turn contains several lots which are employed for the following purposes:

Process Setup—Setup involves pulling entire wafers at each new step and performing analysis.

Design verification and route cleaning—This process involves running a lot through the proposed route to check route integrity.

Lead lots—Based on the electrical data and final structure of the devices, changes may be made to the process flow and experiments may be conducted.

Follow up (several rounds)—Based on limited cross-sections and electrical data, the process flow may be optimized for device performance and yield.

Because each lot is costly, the aggregate cost for performing these design implementation WIP analyses is extremely high. For example, a typical wafer may include approximately 90 identical die. In the case of cross-section analysis, only two die are typically cleaved to evaluate their cross-sections. With respect to inline testing, not all dies are measured and typically less than 25% of the sites are used for inline physical and electrical measurement. The dies not analyzed are simply wasted. The conventional methodology for design development, setup, and verification is extremely costly and inefficient.

One particular example involves the integration of stressed materials to enhance the channel conductivity of the transistor elements by increasing the charge carrier mobility in the channel region for a given channel length. One mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material increases the mobility of electrons, which, in turn, may directly translate into a corresponding increase in the conductivity. On the other hand, compressive strain in the channel region may increase the mobility of holes, thereby providing the potential for enhancing the performance of p-type transistors.

Consequently, it has been proposed to introduce, for instance, a silicon/germanium layer next to the channel region so as to induce a compressive stress that may result in a corresponding strain. The transistor performance of p-channel transistors may be considerably enhanced by the introduction of stress-creating layers next to the channel region. For this purpose a strained silicon/germanium layer may be formed in the drain and source regions of the transistors, wherein the compressively strained drain and source regions create uni-axial strain in the adjacent silicon channel region. When forming the Si/Ge layer, the drain and source regions of the PMOS transistors are selectively recessed, while the NMOS transistors are masked and subsequently the silicon/germanium layer is selectively formed in the PMOS transistor by epitaxial growth. For generating a tensile strain in the silicon channel region, Si/C may be used instead of SiGe.

Referring briefly to FIG. 1, an exemplary transistor device 100 incorporating such a stressed channel region is shown. The device 100 includes a gate electrode 110 formed above a semiconductor layer 120. The gate electrode 110 may be formed of doped polysilicon or other suitable material which is provided above the semiconductor layer 120 and is separated therefrom by a gate insulation layer 130. The semiconductor layer 120 defines a channel region 140 for a finished transistor. Sidewalls of the gate electrode 110 are provided with disposable sidewall spacers 150. The disposable sidewall spacers 150 may consist of any appropriate dielectric material, such a silicon nitride, silicon dioxide, or mixtures thereof. The disposable sidewall spacers 150 may be used as an etch and growth mask in an etch process for forming recesses adjacent the gate electrode 110 and an epitaxial growth process for the formation of embedded stressed semiconductor regions 160 in the recesses. Therefore, the disposable sidewall spacers 150 determine the lateral distance between the gate electrode 110 and the stressed semiconductor regions 160.

The stressed semiconductor regions 160 include a first alloy component and a second alloy component. In an illustrative embodiment, the first alloy component is silicon and the second alloy component is germanium. The growth of the stressed semiconductor regions 160 may performed by using a selective epitaxial growth process using the material of the recess bottom and/or sidewalls as a template. In one illustrative embodiment, an appropriate deposition atmosphere may be established comprising of a silicon-containing precursor material and a germanium-containing precursor material. Typically in selective epitaxial growth processes, the process parameters, such as pressure, temperature, type of carrier gases and the like are selected such that substantially no material is deposited on dielectric surfaces such as the surfaces of the spacer 150 and a possible capping layer (not shown), while a deposition is obtained on exposed surfaces of the first semiconductor layer 120, thereby using this layer as a crystalline template, which substantially determines the crystalline structure of the epitaxially grown stressed semiconductor regions 160. Since the covalent radius of germanium is larger than the covalent radius of the silicon, growing the silicon/germanium material on a silicon template results in a strained silicon/germanium layer which induces a compressive strain in the channel region 140. It should be appreciated that any appropriate stressed semiconductor material may be used, depending on the type of the first semiconductor material and the desired strain type in the first semiconductor material. For example in other embodiments, which use silicon or a silicon-based material as the first semiconductor material, the stressed semiconductor material may be silicon/carbon (SiC) for inducing a tensile strain in the channel region 140.

During the formation of stressed silicon structures, several parameters affect the net stress, which in turn modulates the hole or electron mobility. These parameters include the proximity of the strained material cavity to the gate electrode, the cavity depth, the stress dopant (e.g., germanium or carbon) content of the stressed film, implant conditions, etc. The control of each of these parameters may be attempted to enhance strain and thereby enhance the performance of the completed devices.

After formation of the stressed semiconductor regions 160 many other processes must still be performed to complete the transistor device. Typically, tailored source/drain regions are be formed in the stressed semiconductor regions 160 and possibly into a portion of the channel region 140 using multiple implantation processes. These processes may involve the formation of various spacers other than the spacers 150 having different widths so as to tailor the implant profile. The formation of these spacers may involve depositing a conformal layer, etching the layer to form the spacers, and subsequently removing the spacer after the implantation. Such processing may involve various cleaning processes, etches, and strips. This subsequent processing tends to remove portions of the stressed semiconductor regions 160 due to inherent imperfections in clean, etch, and strip chemistry.

The initial setup of the SiGe process design involves dialing in a spacer etch time, recess etch time, and epitaxial growth time for the stressed material. Typically each of these parameters is dialed in sequentially through individual cross-sections. Moreover, spatial variations in growth rates, etch rates, etc. on a wafer (i.e., within die and/or across wafer) caused by the local pattern density differences, non-uniformity in process conditions, etc. result in variations in the final device structure. These variations are commonly referred to as loading effects. Loading effects complicate the process adjustment activities. Hence, the number of cross-sections required to achieve the appropriate process settings may be significant.

In one example, determining the process settings for the SiGe module includes determining the time required for etching the spacer 150, time required for etching the silicon recess, and time required to grow the silicon-germanium stressed semiconductor regions 160. In the conventional paradigm, each step is typically dialed in sequentially. First, three times for the spacer etch are selected and three different wafers are etched with the three different times. All three wafers are then pulled for destructive testing. From their cross-sections, the spacer etch rate is calculated and another three wafers are etched with the required spacer etch time. Then, three wafers are used to determine the recess etch rate, and similarly, three additional wafers are required to dial in the epitaxial growth time. Thus the exemplary process requires nine wafers and three WIP turns, which is a significant expenditure of resources.

Another issue arising from the conventional methodology described above involves the difficulty in correlating electrical results to the actual process flow. Relating an anomalous electrical result to an actual process step based on only the final cross-section is extremely difficult to accomplish. Pulling wafers at each step is not a feasible alternative. Relating electrical results and physical processing might involve running several rounds of hardware (each requiring 3 months for analysis). A detrimental result on a product wafer leads to direct revenue loss and a mechanism to quickly diagnose problems is currently unavailable.

This section of this document is intended to introduce various aspects of art that may be related to various aspects of the present invention described and/or claimed below. This section provides background information to facilitate a better understanding of the various aspects of the present invention. It should be understood that the statements in this section of this document are to be read in this light, and not as admissions of prior art. The present invention is directed to overcoming, or at least reducing the effects of, one or more of the problems set forth above.

### BRIEF SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

One aspect of the present invention is seen in a method for capturing process history. The method includes performing at least a first process for forming features on a semiconducting substrate. A first cap is formed over a first region of the semiconducting substrate after performing the first process. At least a second process is performed for forming the features in a second region other than the first region while leaving the first cap in place to thereby prevent the features in the first region covered by the first cap from being exposed to the second process. A first characteristic of a first feature is measured in the first region, and a second characteristic of a second feature in the second region is measured.

Another aspect of the present invention is seen in a method for capturing process history that includes processing a semiconducting substrate in a process flow. A first cap is formed over a first region of the semiconducting substrate at a first point in the process flow. A second cap is formed over a second region of the semiconducting substrate at a second point in the process flow. The semiconducting substrate is cross-sectioned across at least the first region and the second region. A first characteristic of the semiconducting substrate is measured in the first region, and a second characteristic of the semiconducting substrate is measured in the second region.

Yet another aspect of the invention is seen in a wafer including a first partially completed feature disposed in a first region. A first cap is formed above the first partially completed feature. A second partially completed feature is disposed in a second region of the wafer different than the first region. The second partially completed feature is at a later stage of completion than the first partially completed feature.

### BRIEF DESCRIPTION OF THE SEVERAL VIEWS OF THE DRAWINGS

The invention will hereafter be described with reference to the accompanying drawings, wherein like reference numerals denote like elements, and:

FIG. 1 is a cross-section view of an exemplary prior art semiconductor device including recessed stressed regions;

FIG. 2 is a diagram of a wafer including caps formed to preserve process history in accordance with one illustrative embodiment of the invention; and

FIGS. 3 and 4 are cross-section views of partially processed wafers illustrating the disposition of the caps to preserve process history.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

One or more specific embodiments of the present invention will be described below. It is specifically intended that the present invention not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the present invention unless explicitly indicated as being “critical” or “essential.”

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

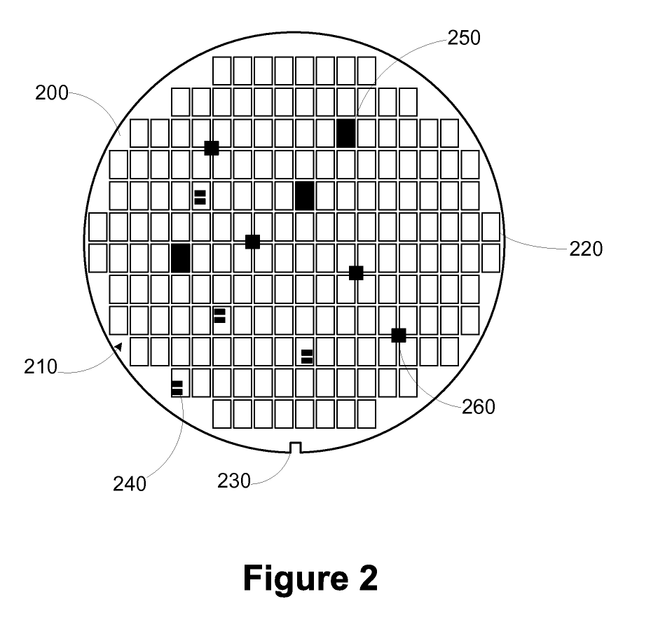

Referring now to the drawings wherein like reference numbers correspond to similar components throughout the several views and, specifically, referring to FIG. 2, the present invention shall be described in the context of an illustrative wafer map of a semiconductor wafer 200. Each wafer 200 can accommodate a number of flashes (and by derivation, a number of devices) usually through a Cartesian grid layout 210 called a stepping pattern. The device that is formed on the surface of a wafer is called a die 220. A notch 230 is provided for aligning the wafer 200 in a particular tool. Of course, other features may be provided for alignment, such as a flat edge portion.

In accordance with embodiments of the present invention, the wafer 200 can be a monitor wafer (i.e., representing a complete lot of wafers each getting identical processing conditions) or a product/development wafer (i.e., that might be processed slightly differently from the other wafers in the lot) used to characterize a process flow through multiple stages and over multiple points in time. To preserve the processing history of the wafer 200, caps 240, 250, 260 are formed at various points in the process flow. The area covered by each cap 240, 250, 260 may vary depending on the particular history information that is desired to be preserved. For instance, the cap 240 covers a portion of a die 220, the cap 250 covers an entire die 220, and the cap 260 covers a region defined between multiple die 220 in which a test structure may be formed (i.e., in the scribe line region between adjacent die 220). The particular sizes, number, and placement of the caps 240, 250, 260 may vary depending on the particular embodiment. Within a single die a particular pattern may be seen in multiple locations. Caps, such as the cap 240, may be placed over different regions of these patterns on the same die 220 at different process points to identify when particular changes to the devices take place.

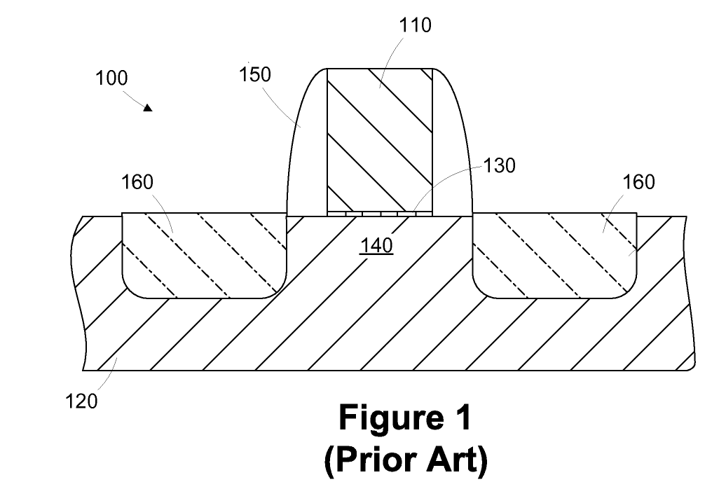

Generally, the caps 240, 250, 260 preserve the structural history of a particular lot of wafers by partially covering small areas on a wafer at different stages of the processing. This capping prevents the area protected from further processing without influencing the processing of the uncovered areas. After processing of the wafer 200, has progressed to a desired point, the covered areas may be separately analyzed to identify the history of the wafer 200 throughout the process flow. Hence, a single wafer may be used to capture the structural evolution of the devices. In the context of a transistor similar to the transistor 100 of FIG. 1, the protected regions may be shielded from SiGe loss.

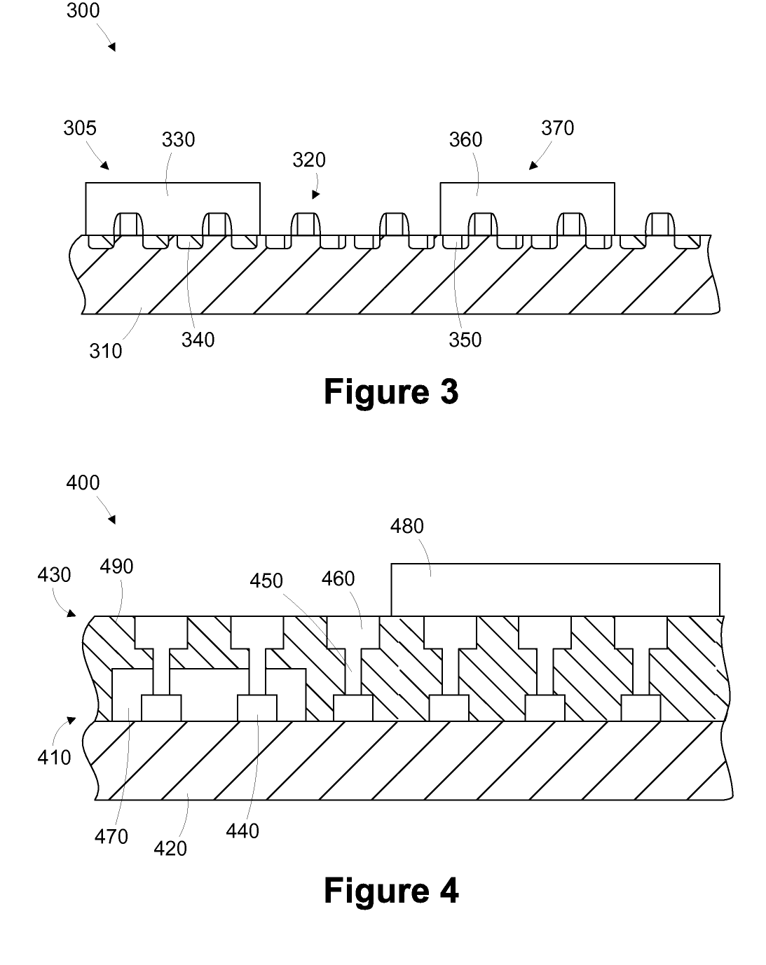

FIG. 3 illustrates a cross-section of a wafer 300. As seen in FIG. 3, a first region 305 is defined on a semiconductor layer 310. For example, the first region 305 may include semiconductor devices, such as transistors 320. The fabrication of a transistor 320 includes many discrete steps. For purposes of the following illustration, it is assumed that the first region 305 includes transistors 320 similar to the transistor 100 of FIG. 1 formed with recessed stress layers adjacent the channel regions of the device to enhance carrier mobility. Also, not all features of the devices are shown. For example, isolation structures commonly formed between transistors are omitted. Also, the source/drain regions are not shown in detail with respect to profile.

A first cap 330 may be formed over a portion of the region 305 after formation of the stressed semiconductor regions 340. Appropriate masking and deposition processes known in the art may be used to form the first cap 330. In one embodiment, the material of the first cap 330 may be a dielectric material. For example, in an actual device, after the fabrication of the completed transistors 320, an interlevel dielectric layer (ILD) is typically formed over the region 305. Subsequently, vias and trenches may be formed in the ILD to contact the underlying devices. Various materials, including low-k dielectric materials, may be used to form the ILD. In the illustrated embodiment, the first cap 330 may be formed using the same material as the subsequent ILD. In this manner, the cap 330 shields the underlying features and is compatible with future materials and processes expected to be performed.

At same later point in the processing, such as after the implants to form source/drain regions 350 in the stressed semiconductor regions 340, a second cap 360 may be formed over a second region 370 to isolate the underlying features from subsequent processing. At a later point in time, a cross-section analysis may be completed to compare the material loss after the various etch and strip processes used to form spacers for the implants (e.g., source/drain, extension, halo, etc.), as preserved by the cap 360, to the initial fill height of the stressed semiconductor regions 340 that was preserved by cap 330. The number of caps 330, 360 formed and the timing at which the caps 330, 360 are formed may vary depending on the particular process history to be analyzed.

Referring now to FIG. 4, a cross-section of a wafer 400 is provided. The wafer 400 includes multiple layers, including a device layer 410 formed on a base layer 420, and a metallization layer 430 formed over the device layer 410. The device layer 410 include features 440, such as transistors, and the metallization layer 430 includes conductive vias 450 and trenches 460 communicating with the underlying features 440. A first cap 470 was formed over a portion of the features 440 to preserve process history information (e.g., SiGe fill height). A second cap 480 was formed over a portion of the trenches 460 to preserve history associated with the metallization layer 430 (i.e., dishing, erosion, etc.).

In some embodiments, the material of the cap 470 is the same material as a dielectric layer 490 separating the device layer 410 from the metallization layer 430. In such a case, the etch procedures used to form the vias 450 and trenches 460 will also form vias 450 and trenches 460 that connect to the features 440 beneath the cap 470. However, the history information associated with the features 440 preserved by the cap 470 may not be located in the region contacted by the via 450. In cases, where it is not desirable to expose the feature 440 beneath the cap 470 with the via etch, the cap 470 may include an additional layer, such as an etch stop layer, or the cap 470 may be formed from a different material entirely, such that the process history associated with the features 440 may be preserved.

Returning to FIG. 2, the caps 240, 250, 260 may be formed on the same layers of the die 220, as in FIG. 3, or they may be formed on different layers, as in FIG. 4. The particular number of caps and the layers on which they are formed may vary widely depending on the particular embodiment and the process history sought to be preserved.

A particular process history example is now described with reference to the tuning process for a device with recessed stressed regions, such as the device of FIG. 1. By using the caps 240, 250, 260 less wafers may be used for tuning the process for spacer etch, recess etch, and epitaxial growth. In accordance with one embodiment of the present invention, three wafers may be etched with three different spacer etch times. One or more caps 240, 250, 260 are provided over specific regions on all three wafers to isolate the effect of the spacer etch. The same three wafers would then be subjected to a recess etch with three different recess etch times. The recess etch would not affect the regions previously capped for the spacer etch history preservation. Again, one or more caps 240, 250, 260 would be formed over the specific recessed regions to preserve the cumulative effect of the spacer and recess etches. Subsequently, a silicon-germanium (i.e., or other stress dopant, such as carbon) epitaxial growth process would be performed on the three wafers using three different growth times. The monitor wafers would then be cross-sectioned at multiple sites to de-convolute the spacer, recess, epi etch/growth rates in parallel. Using the caps 240, 250, 260 in this manner reduces the time required to tune the process and also reduces the wafer requirements by a factor of three. Hence, by capping and preserving the response to each variable at every step and using a small range of process variables, it is possible to triangulate the entire process in the time that it takes to process a single wafer through the SiGe sector.

After the initial setup, the selective capping scheme can be used to efficiently optimize the process including SiGe loss. It is important to determine and monitor SiGe loss through the entire processing sequence since it causes reduction in device performance and introduces reliability issues. By capping small areas at various steps in the flow it is possible to isolate the SiGe loss due to different cleans, etches, and strips. In some embodiments a dedicated test structure may be provided to monitor this loss through the entire development and production cycle, as the SiGe loss is very sensitive to process changes. By placing caps over different functional regions of a die, loading effects for the different macros (e.g., SRAM, logic, etc.) at significant steps in the process flow may be monitored.

Selectively capping areas to preserve process history has numerous application and advantages. In the case of production wafers, selective capping may still be used to collect process snapshots without requiring destruction of the entire wafer. After processing of the wafer has been completed, uncapped die may be tested, singulated, and packaged in the same manner as typical production wafers. However, those die with caps to preserve process history may be separated from the unaffected die and examined (e.g., cross-sectioned) to extract the process history information. The process history also allows fabrication engineering personnel to understand what was different about a particular “good” lot without ambiguity and without trying to duplicate the exact conditions.

During process optimization the capture of structural information about the device helps allow correlating electrical results to processing conditions without running additional cycles. In addition, by capturing the entire process flow on a single wafer it would be possible to compare processes in different fabrication facilities. Anomalous results may be related to actual processing conditions. Over time, a library of monitor wafers with selectively capped regions may be stored to record and document any process shifts.

With respect to production applications, capped monitor wafers may be used to compare SiGe processing between fabrication facilities. For various structures, such as recessed stressed material regions, trench isolation regions, etc. material losses may be analyzed at different steps using a single monitor wafer. Similarly, caps may be provided at different steps to monitor device structures, particularly before a subtractive process (e.g., etch, spacer removal, etc.). Selective capping also allow dopant distributions to be monitored at different steps.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

We claim:

1. A method for capturing process history, comprising:
performing at least a first process for forming features on a semiconducting substrate;
forming a first cap over a first region of the semiconducting substrate after performing the first process;
performing at least a second process for forming the features in a second region other than the first region while leaving the first cap in place to thereby prevent the features in the first region covered by the first cap from being exposed to the second process;
measuring a first characteristic of a first feature in the first region; and
measuring a second characteristic of a second feature in the second region.

2. The method of claim 1, further comprising:
forming a second cap over at least a portion of the second region after performing the second process;
performing at least a third process for forming the features, the third process affecting the features in a third region other than the portions of the first and second regions covered by the first and second caps; and
measuring a third characteristic of a third feature in the third region.

3. The method of claim 1, further comprising determining at least one recipe parameter for the first process or the second process based on the first and second measured characteristics.

4. The method of claim 2, further comprising determining at least one recipe parameter for the first process, the second process, or the third process based on at least one of the first, second, or third measured characteristics.

5. The method of claim 1, wherein the first process comprises forming a material, the second process comprises a material removal process, and the method further comprises comparing the first and second measured characteristics to determine a material loss due to the second process.

6. The method of claim 5, wherein the material comprises a stressed material, and the first process comprises forming the stressed material in a recess defined in a semiconductor layer.

7. The method of claim 1, wherein the first cap covers a portion of a die region defined on the semiconducting substrate.

8. The method of claim 1, wherein the first cap covers an entire die region defined on the semiconducting substrate.

9. The method of claim 1, wherein the first cap covers a test structure disposed between die regions defined on the semiconducting substrate.

10. A method, comprising:
processing a semiconducting substrate in a process flow;
forming a first cap over a first region of the semiconducting substrate at a first point in the process flow;
forming a second cap over a second region of the semiconducting substrate at a second point in the process flow;
cross-sectioning the semiconducting substrate across at least the first region and the second region;
measuring a first characteristic of the semiconducting substrate in the first region; and
measuring a second characteristic of the semiconducting substrate in the second region.

11. The method of claim 10, wherein the first and second caps are disposed above a first layer.

12. The method of claim 10, wherein the first cap is disposed above a first layer and below a second layer, and the second cap is disposed above the second layer.

13. The method of claim 12, wherein the first layer comprises a device layer, and the second layer comprises a metallization layer.

14. The method of claim 10, wherein the first cap covers a portion of a die region.

15. The method of claim 10, wherein the first cap covers an entire die region.

16. The method of claim 10, wherein the first cap covers a test structure disposed between die regions.

17. The method of claim 10, further comprising determining at least one recipe parameter for processing subsequent semiconducting substrates based on the first and second measured characteristics.

18. The method of claim 10, wherein the first and second characteristics comprise material thickness characteristics.

19. The method of claim 10, wherein the first and second characteristics comprise spacer width characteristics.

20. The method of claim 10, wherein the first and second characteristics comprise recess depth characteristics.

21. The method of claim 10, wherein the first and second characteristics comprise dopant profile characteristics.

22. A wafer, comprising:
a first partially completed feature disposed in a first region of the wafer;
a first cap formed above the first partially completed feature; and
a second partially completed feature disposed in a second region of the wafer different than the first region, the second partially completed feature being at a later stage of completion than the first partially completed feature.

23. The wafer of claim 22, comprising a second cap formed above the second partially completed feature.

24. The wafer of claim 23, further comprising a third feature disposed in a third region of the wafer different than the first and second regions, the third feature being at a later stage of completion than the second partially completed feature.
